(19) United States
(12) Patent Application Publication
(10) Pub. No.: US 2016/0323060 A1
(43) Pub. Date: Nov. 3, 2016

(54) APPARATUS, COMPUTER READABLE MEDIUM, AND METHOD FOR HIGHER QAM IN A HIGH EFFICIENCY WIRELESS LOCAL-AREA NETWORK

(71) Applicant: Intel IP Corporation, Santa Clara, CA (US)

(72) Inventors: Mohamed K. Hassanin, Sunnyvale, CA (US); Thomas J. Kenney, Portland, OR (US); Shahrnaz Azizi, Cupertino, CA (US); Eldad Perahia, Portland, OR (US); Ahmed Gamal Helmy Mohamed, Richardson, TX (US)

(21) Appl. No.: 14/845,958

(22) Filed: Sep. 4, 2015

Related U.S. Application Data
(60) Provisional application No. 62/153,630, filed on Apr. 28, 2015.

(51) Int. Cl. H04L 1/00; H03M 13/11

(52) U.S. Cl. CPC H04L 1/0041; H03M 13/1102; H04W 84/12

(57) ABSTRACT

A high-efficiency wireless local-area network (HEW) device including transceiver circuitry and processing circuitry is disclosed. The transceiver circuitry and processing circuitry may be configured to encode or decode a packet using a low-density parity check (LDPC) code four times longer than a legacy LDPC code and in accordance with a channel code, and to transmit or receive the packet. The LDPC code may be four times longer than the legacy LDPC code. The LDPC may be 7776 bits and the legacy LDPC code may be 1944 bits. The packet may be transmitted or received in accordance with 1024 QAM. The channel code may be 1/2, 2/3, 3/4, or 5/6. The LDPC subcarrier mapping may have an increased distance between sub-carriers compared with a legacy Institute of Electrical and Electronic Engineers 802.11 standard.

### PRIORITY CLAIM

This application claims the benefit of priority under 35 USC 119(e) to U.S. Provisional Patent Application Ser. No. 62/153,630, filed Apr. 28, 2015, which is incorporated herein by reference in its entirety.

### TECHNICAL FIELD

Embodiments relate to wireless devices. Some embodiments relate to Institute of Electrical and Electronic Engineers (IEEE) 802.11. Some embodiments relate to high-efficiency wireless local-area networks (HEWs). Some embodiments relate to IEEE 802.11ax. Some embodiments relate to using 1024 quadrature amplitude modulation (QAM) in a wireless local area network (WLAN). Some embodiments relate to a low-density parity check (LDPC) subcarrier mapping and/or code word size for LDPC.

### BACKGROUND

Efficient use of the resources of a wireless local-area network (WLAN) is important to provide bandwidth and acceptable response times to the users of the WLAN. Moreover, wireless devices may need to operate with both newer protocols and with legacy device protocols.

Additionally, there may be errors in receiving data, and different ways of transmitting the data over the wireless medium may reduce the number of or may provide the receiver with additional information that may enable the receiver to correct errors.

### BRIEF DESCRIPTION OF THE DRAWINGS

The present disclosure is illustrated by way of example and not limitation in the figures of the accompanying drawings, in which like references indicate similar elements and in which:

FIG. 1 illustrates a wireless network in accordance with some embodiments;

FIG. 2 illustrates the results of a simulation comparing 1024 QAM modulation with 1/2 channel code to 64 QAM with 5/6 channel code with a 4× code word for LDPC in accordance with some embodiments;

FIG. 3 illustrates the results of a simulation comparing 1024 QAM modulation with 1/2 channel code to 64 QAM with 5/6 channel code with a 1× code word for LDPC in accordance with some embodiments;

FIG. 4 illustrates a table of modulation orders with channel codes 404 used for the modulation orders in accordance with some embodiments;

FIG. 5 illustrates tables with tone mapping adjustments for LPDCs four times longer than legacy LPDCs in accordance with some embodiments; and

FIG. 6 illustrates a HEW station in accordance with some embodiments.

### DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

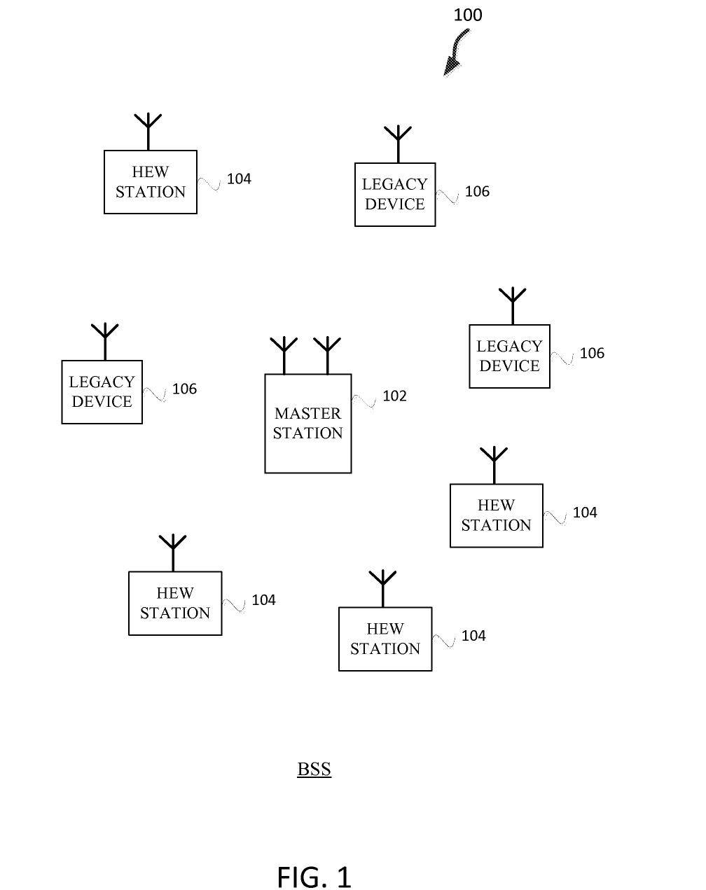

FIG. 1 illustrates a WLAN 100 in accordance with some embodiments. The WLAN may comprise a basis service set (BSS) 100 that may include a master station 102, which may be an AP, a plurality of high-efficiency wireless (HEW) (e.g., IEEE 802.1 lax) STAs 104 and a plurality of legacy (e.g., IEEE 802.11n/ac) devices 106.

The master station 102 may be an AP using the IEEE 802.11 to transmit and receive. The master station 102 may be a base station. The master station 102 may use other communications protocols as well as the IEEE 802.11 protocol. The IEEE 802.11 protocol may be IEEE 802.11 ax. The IEEE 802.11 protocol may include using orthogonal frequency division multiple-access (OFDMA), time division multiple access (TDMA), and/or code division multiple access (CDMA). The IEEE 802.11 protocol may include a multiple access technique. For example, the IEEE 802.11 protocol may include space-division multiple access (SDMA) and/or multiple-user multiple-input multiple-output (MU-MIMO).

The legacy devices 106 may operate in accordance with one or more of IEEE 802.11 a/b/g/n/ac/ad/af/ah/aj, or another legacy wireless communication standard. The legacy devices 106 may be STAs or IEEE STAs. The HEW STAs 104 may be wireless transmit and receive devices such as cellular telephone, smart telephone, handheld wireless device, wireless glasses, wireless watch, wireless personal device, tablet, or another device that may be transmitting and receiving using the IEEE 802.11 protocol such as IEEE 802.11ax or another wireless protocol. In some embodiments, the HEW STAs 104 may be termed high efficiency (HE) stations.

The master station 102 may communicate with legacy devices 106 in accordance with legacy IEEE 802.11 communication techniques. In example embodiments, the master station 102 may also be configured to communicate with HEW STAs 104 in accordance with legacy IEEE 802.11 communication techniques.

In some embodiments, a HEW frame may be configurable to have the same bandwidth as a subchannel. The bandwidth of a subchannel may be 20 MHz, 40 MHz, or 80 MHz, 160 MHz, 320 MHz contiguous bandwidths or an 80+80 MHz (160 MHz) non-contiguous bandwidth. In some embodiments, the bandwidth of a subchannel may be 1 MHz, 1.25 MHz, 2.03 MHz, 2.5 MHz, 5 MHz and 10 MHz, or a combination thereof or another bandwidth that is less or equal to the available bandwidth may also be used. In some embodiments the bandwidth of the subchannels may be based on a number of active subcarriers. In some embodiments the bandwidth of the subchannels are multiples of 26 (e.g., 26, 52, 104, etc.) active subcarriers or tones that are spaced by 20 MHz. In some embodiments the bandwidth of the subchannels is 256 tones spaced by 20 MHz. In some embodiments the subchannels are multiple of 26 tones or a multiple of 20 MHz. In some embodiments a 20 MHz subchannel may comprise 256 tones for a 256 point Fast Fourier Transform (FFT).

A HEW frame may be configured for transmitting a number of spatial streams, which may be in accordance with MU-MIMO. In other embodiments, the master station 102, HEW STA 104, and/or legacy device 106 may also implement different technologies such as code division multiple access (CDMA) 2000, CDMA 2000 1×, CDMA 2000 Evolution-Data Optimized (EV-DO), Interim Standard 2000 (IS-2000), Interim Standard 95 (IS-95), Interim Standard 856 (IS-856), Long Term Evolution (LTE), Global System for Mobile communications (GSM), Enhanced Data rates for GSM Evolution (EDGE), GSM EDGE (GERAN), IEEE 802.16 (i.e., Worldwide Interoperability for Microwave Access (WiMAX)), BlueTooth®, or other technologies.

Some embodiments relate to HEW communications. In accordance with some IEEE 802.11 ax embodiments, a master station 102 may operate as a master station which may be arranged to contend for a wireless medium (e.g., during a contention period) to receive exclusive control of the medium for an HEW control period. In some embodiments, the HEW control period may be termed a transmission opportunity (TXOP). The master station 102 may transmit a HEW master-sync transmission, which may be a trigger frame or HEW control and schedule transmission, at the beginning of the HEW control period. The master station 102 may transmit a time duration of the TXOP and sub-channel information. During the HEW control period, HEW STAs 104 may communicate with the master station 102 in accordance with a non-contention based multiple access technique such as OFDMA or MU-MIMO. This is unlike conventional WLAN communications in which devices communicate in accordance with a contention-based communication technique, rather than a multiple access technique. During the HEW control period, the master station 102 may communicate with HEW stations 104 using one or more HEW frames. During the HEW control period, the HEW STAs 104 may operate on a sub-channel smaller than the operating range of the master station 102. During the HEW control period, legacy stations refrain from communicating.

In accordance with some embodiments, during the master-sync transmission the HEW STAs 104 may contend for the wireless medium with the legacy devices 106 being excluded from contending for the wireless medium during the master-sync transmission. In some embodiments the trigger frame may indicate an uplink (UL) UL-MU-MIMO and/or UL OFDMA control period.

In some embodiments, the multiple-access technique used during the HEW control period may be a scheduled OFDMA technique, although this is not a requirement. In some embodiments, the multiple access technique may be a time-division multiple access (TDMA) technique or a frequency division multiple access (FDMA) technique. In some embodiments, the multiple access technique may be a space-division multiple access (SDMA) technique.

The master station 102 may also communicate with legacy stations 106 and/or HEW stations 104 in accordance with legacy IEEE 802.11 communication techniques. In some embodiments, the master station 102 may also be configurable to communicate with HEW stations 104 outside the HEW control period in accordance with legacy IEEE 802.11 communication techniques, although this is not a requirement.

In example embodiments, the HEW device 104 and/or the master station 102 are configured to perform the methods and functions herein described in conjunction with FIGS. 1-6.

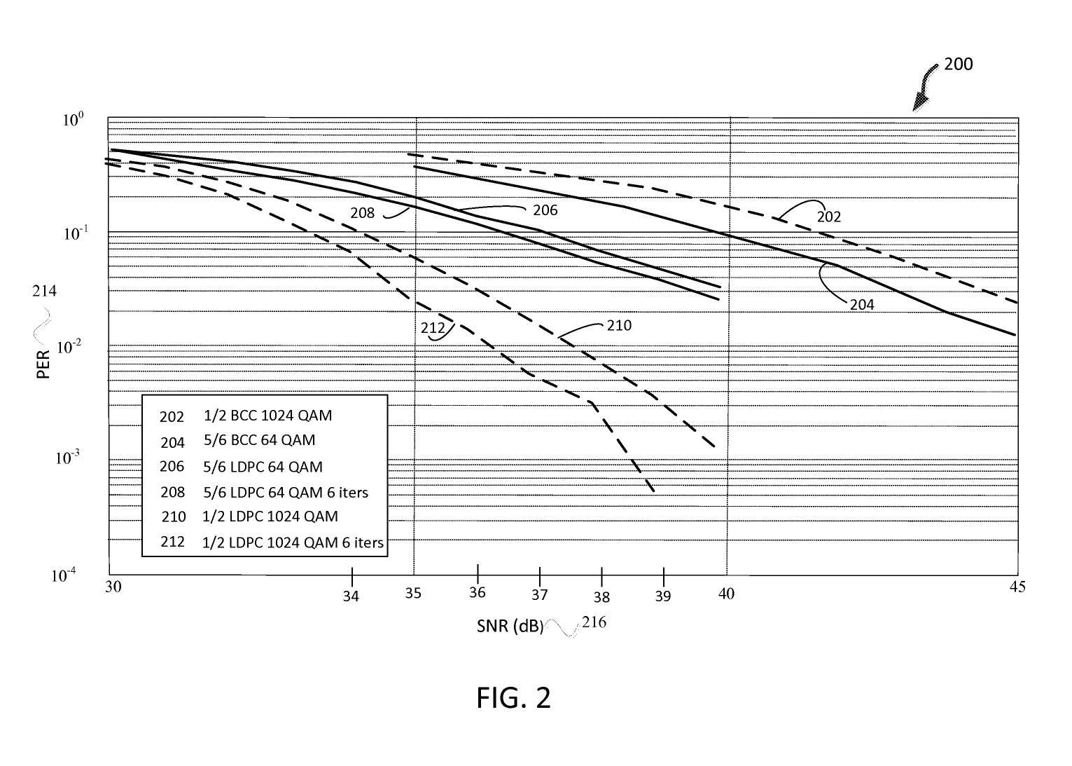

FIG. 2 illustrates the results 200 of a simulation comparing 1024 QAM modulation with 1/2 channel code to 64 QAM with 5/6 channel code with a 4× code word for LDPC in accordance with some embodiments. The simulation was run with a spectral efficiency of five bits per second per hertz with a 20 MHz channel. The simulation was further run with very-high throughput packets, spatial streams (ss) equal to 260 megabits per second (Mbps), and with impairments including power amplifier non-linearity, frequency offset, and phase noise. Illustrated in FIG. 2 are packet error rate (PER) 214 along a vertical axis, signal to noise ratio (SNR) 216 along a horizontal axis, 1/2 binary convolution coding (BCC) 1024 QAM 202, 5/6 BCC 64 QAM 204, 5/6 LDPC 64 QAM 206, 5/6 LDPC 64 QAM 6 iterative (iters) 208, 1/2 LDPC 1024 QAM 210, and 1/2 LDPC 1024 QAM 6 iters 212. A LDPC code word size of 7776 bits was used for the simulation. The code word size of 7776 bits is four times the LDPC code word size used in legacy IEEE standards. The legacy code word size used may be 648 bits, 1296 bits, and 1944 bits. The fraction at the beginning 1/2 or 5/6 indicates a channel code where the first number is the information and the second number is total number of bits. For example, 5/6 indicates that for every 6 bits in a code word that 5 bits is for actual information and 1 bit is for error detection coding.

A comparison is made between 1024 QAM and 64 QAM where the channel code is adjusted so both will yield the same effective code rate. 1024 QAM modulation with a 1/2 channel code and 64 QAM with a channel code 5/6 yield the same effective code rate with both having log (1024)*0.5=log (64)*5/6, which is equal to 5 bits per second per Hertz. So, 1/2 BCC 1024 QAM 202 and 5/6 BCC 64 QAM have the same effective code rate; 1/2 LDPC 1024 QAM 210 and 5/6 LDPC 64 QAM 206 have the same effective code rate; and, 1/2 LDPC 1024 QAM 6 iters and 5/6 LDPC 64 QAM 6 iters have the same effective code rate.

The performance of 1/2 BCC 1024 QAM 202 is about 1 dB worse than 5/6 BCC 64 QAM 204. For example, 1/2 BCC 1024 QAM 202 crosses the 10⁻¹ (0.1) PER 214 line at about 41 dB SNR 216, and 5/6 BCC 64 QAM 204 crosses the 0.1 PER 214 line at about 40 dB SNR 216, so 5/6 BCC 64 QAM 204 performs a little bit better than 1/2 BCC 1024 QAM 202. However, when LDPC is used with 1024 QAM then 1/2 LDPC 1024 QAM 210 performs better than 5/6 LDPC 64 QAM 206.

For example, 5/6 LDPC 64 QAM 206 crosses the 0.1 PER 214 line at close to 37 dB, and 1/2 LDPC 1024 QAM 210 crosses the 0.1 PER 214 line at close to 34 dB, so the 1/2 LDPC 1024 QAM 210 performs better by about 3 dB sensitivity at a PER of 0.1.

The performance of iterative decoding is illustrated with 5/6 LDPC 64 QAM 6 iters 208 and 1/2 LDPC 1024 QAM 6 iters 212. The performance of 5/6 LDPC 64 QAM 6 iters 208 and 1/2 LDPC 1024 QAM 6 iters 212 illustrate that the improved performance is due to the LDPC code and not dependent on the way MIMO channel decoding is performed. The iterative decoding uses a method of decoding that maintains a separation of MIMO detection and channel decoding and iterates between the MIMO detection and the channel decoding. In the iterative method, the MIMO detector passes soft code input values of log likelihood ratios (LLR) to the channel decoder, and the channel decoder passes the decoded soft information of the channel code word (LLR) back to the MIMO detector which combines that with the observed MIMO.

Longer length LDPC codes (e.g., here 4 times the length of the legacy LDPC codes) have more coding gain and their structure is less susceptible to the kind of errors that higher order modulation induces. For example, the LDPC codes may be less sensitive to error vector magnitude (EVM) distortion. In higher order modulation such as 1024 QAM, the least significant bit (LSB) may be severely affected by the poor resolution and EVM effects. In some embodiments, a different code rate for each modulation bit is used, but this may increase the complexity of coding and decoding and this is not supported in IEEE 802.11 standards. In some embodiments, the master station 102 and/or HEW device 104 is configured to use bit interleaved coded modulation (BICM) which may overcome the LSB being severely affected by EVM distortion.

In some embodiments, the master station 102 and/or HEW station 104 may be configured for soft decoding of BICM LDPC codes, which may provide good performance for LDPC and 1024 QAM. The results 200 illustrate that high order modulation with lower channel code rates can outperform lower order modulation with high channel code rates. The results 200 also illustrate that LDPCs that use four times longer than legacy code words outperform BCC.

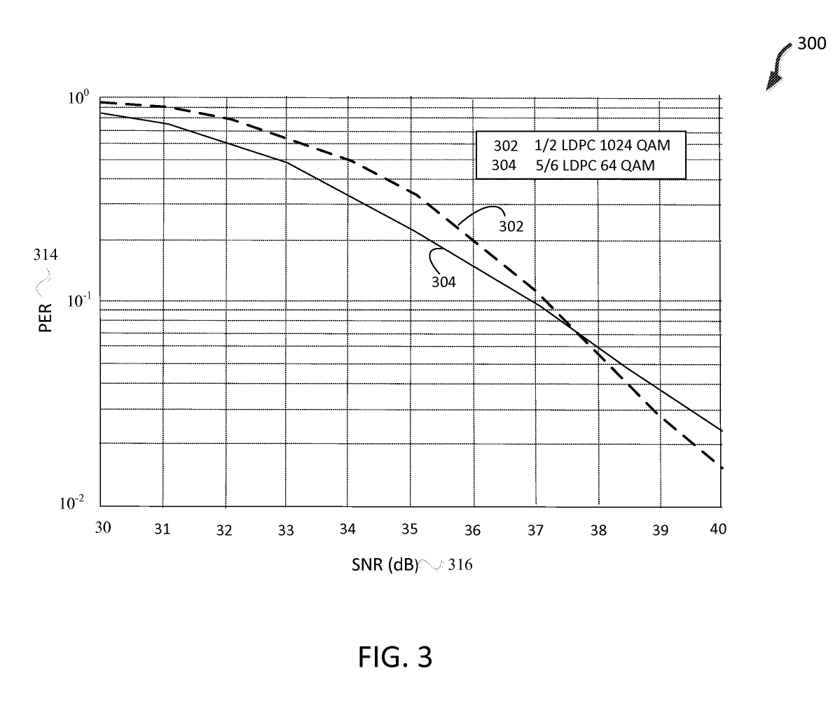

FIG. 3 illustrates the results 300 of a simulation comparing 1024 QAM modulation with 1/2 channel code to 64 QAM with 5/6 channel code with a 1× code word for LDPC in accordance with some embodiments. Illustrated in FIG. 3 are PER 314 along a vertical axis, SNR 316 along a horizontal axis, 1/2 LDPC 1024 QAM 302, and 5/6 LDPC 64 QAM 304. With only the 1× code word, the 5/6 LDPC 64 QAM 304 outperforms the 1024 QAM 302 up until between 37 and 38 dB where 1/2 LDPC 1024 QAM 302 starts to outperform 5/6 LDPC 64 QAM 304. The 1/2 LDPC 1024 QAM 302 has a better diversity order as can be determined from the slope of the PER curves. Moreover, the performance loss of the 1/2 LDPC 1024 QAM 302 is only 0.3 dB at 0.1 PER compared with the 5/6 LDPC 64 QAM 304.

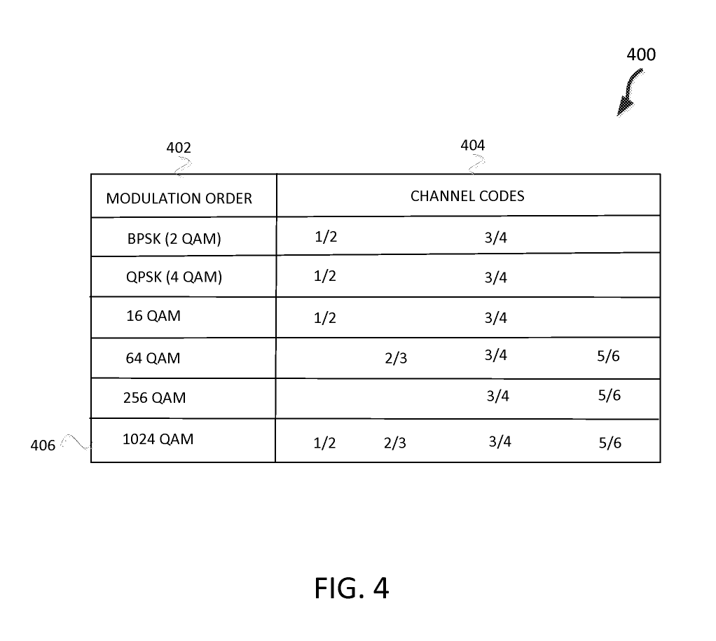

FIG. 4 illustrates a table 400 of modulation orders 402 with channel codes 404 used for the modulation orders in accordance with some embodiments. Illustrated in FIG. 4 are modulation orders 402 with the channel codes 404 that may be included in standards. In some legacy standards, lower channel codes are not included in some of the higher modulation orders. For example, 1/2 channel code is not included with 64 QAM in IEEE 802.11ac. In some embodiments the master station 102 and/or HEW station 104 may be configured to transmit with a modulation order of 1024 QAM and channel codes of 1/2 and 2/3 as disclosed in row 406 of table 400. As disclosed in conjunction with FIG. 2, a lower channel codes such as 1/2 may provide better performance than lower modulation orders with higher channel codes. For example, as disclosed in the simulation results 200, a modulation order of 1024 QAM with a channel code of 1/2 may perform better than a modulation order of 64 QAM with a channel code of 5/6.

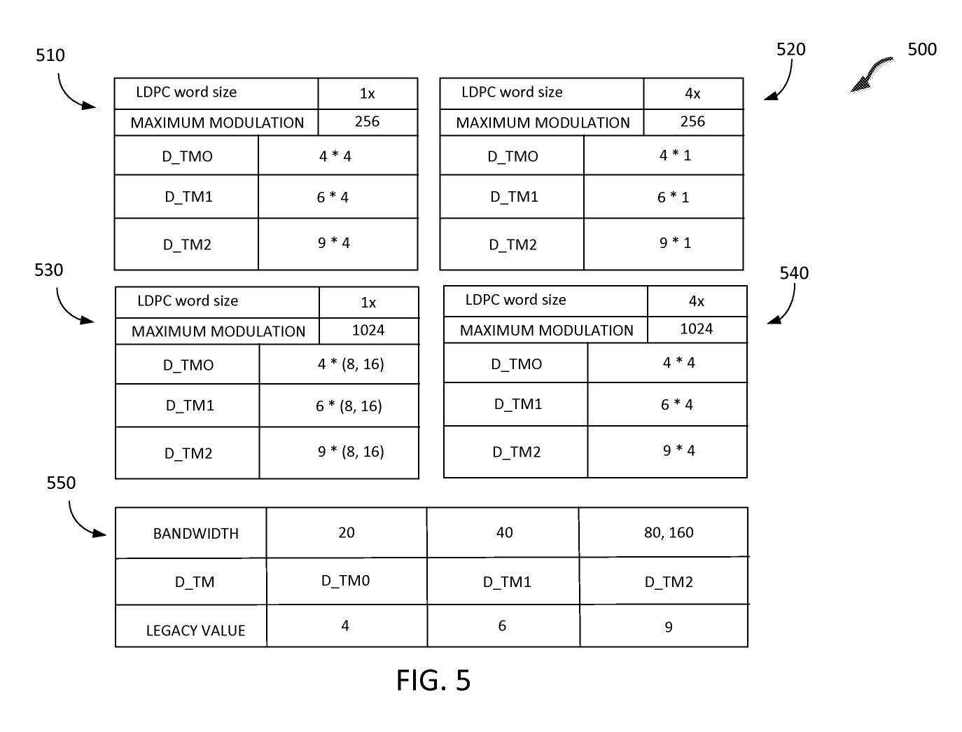

FIG. 5 illustrates tables 510, 520, 530, 540, 550 with tone mapping adjustments for LPDCs four times longer than legacy LPDCs in accordance with some embodiments. In some embodiments tone mapping is termed modulation mapping. The tone mappings indicate a mapping for consecutive QAM symbols to non-consecutive subcarriers for the sub-channel the packet is to be transmitted within. A sub-channel may have a number of active sub-carriers that are used to transmit the QAM symbols. The legacy values in table 550 indicate that every 4th active sub-carrier (separation distance D_TM0) should be used for consecutive QAM symbols for a 20 MHz bandwidth for the sub-channel, that every 6th active sub-carrier (separation distance D_TM1) should be used for consecutive QAM symbols for a 40 MHz bandwidth for the sub-channel, and that every 9th active sub-carrier (separation distance D_TM2) should be used for consecutive QAM symbols for 80 MHz or 160 MHz bandwidth for the sub-channel. The tone mapping may be termed a LDPC subcarrier mapping in accordance with some embodiments.

The tone mapping table 510 illustrates tone mapping adjustments to legacy tone mappings of table 550 for an LDPC word size of one times (1×) the legacy code word size of 1944 bits where a modulation order of a maximum of 256 QAM will be used. Table 510 in conjunction with table 550 indicates that the legacy tone mappings should be adjusted as follows: for a 20 MHz bandwidth the separation distance of the subcarriers (D_TM0) should be adjusted to be four times (4*4) the legacy value, for a 40 MHz bandwidth the separation distance of the subcarriers (D_TM1) should be adjusted to be four times (4*6) the legacy values, and for a 80 MHz bandwidth the separation distance of the subcarriers (D_TM2) should be adjusted to be four time (9*4) the legacy values.

The tone mapping table 520 illustrates tone mapping adjustments to legacy tone mappings of table 550 for an LDPC word size of four times (4×) the legacy code word size of 1944 bits where a modulation order of a maximum of 256 QAM will be used. Table 520 in conjunction with table 550 indicates that the legacy tone mappings for a LDPC word size of four times a legacy value with a maximum modulation of 256 QAM should be adjusted as follows: for a 20 MHz bandwidth the separation distance of the subcarriers (D_TM0) should be adjusted to be one times (4*1) the legacy value, for a 40 MHz bandwidth the separation distance of the subcarriers (D_TM1) should be adjusted to be one times (6*1) the legacy values, and for a 80 MHz bandwidth the separation distance of the subcarriers (D_TM2) should be adjusted to be four time (9*1) the legacy values.

The tone mapping table 530 illustrates tone mapping adjustments to legacy tone mappings of table 550 for an LDPC word size of one times (1×) the legacy code word size of 1944 bits where a modulation order of a maximum of 1024 QAM will be used. Table 530 in conjunction with table 550 indicates that the legacy tone mappings for LDPC word size of one times (1×) the legacy code word size and maximum modulation 1024 QAM should be adjusted as follows: for a 20 MHz bandwidth the separation distance of the subcarriers (D_TM0) should be adjusted to be eight (8) or sixteen (16) times (4*8 or 16) the legacy value, for a 40 MHz bandwidth the separation distance of the subcarriers (D_TM1) should be adjusted to be eight (8) or sixteen (16) times (6*8 or 16) the legacy values, and for a 80 MHz bandwidth the separation distance of the subcarriers (D_TM2) should be adjusted to be eight (8) or sixteen (16) times (9*8 or 16) the legacy values.

The tone mapping table 540 illustrates tone mapping adjustments to legacy tone mappings of table 550 for an LDPC word size of four times (4×) the legacy code word size of 1944 bits where a modulation order of a maximum of 1024 QAM will be used. Table 540 in conjunction with table 550 indicates that the legacy tone mappings for LDPC word size of four times (4×) the legacy code word size and maximum modulation 1024 QAM should be adjusted as follows: for a 20 MHz bandwidth the separation distance of the subcarriers (D_TM0) should be adjusted to be four times (4*4) the legacy value, for a 40 MHz bandwidth the separation distance of the subcarriers (D_TM1) should be adjusted to be four times (4*6) the legacy values, and for a 80 MHz bandwidth the separation distance of the subcarriers (D_TM2) should be adjusted to be four time (9*4) the legacy values.

The output of the LDPC tone mapper may be \acute{d}_{k,l,n}, where \acute{d}_{k,l,n}=d_{t(k),l,n}, and where

$$t ( k ) = {D}_{TM} * ( k mod \frac{ {N}_{SD}}{{D}_{TM}} ) + ⌊ \frac{k * {D}_{TM}}{{N}_{SD}} ⌋ ;$$

k=0, 1, . . . , N_{SD}−1; l=1, . . . , N_{SS}; n=0, 1, . . . , N_{SYM}−1; N_{SS} is the number of spatial streams; N_{SYM} is the number of OFDM symbols; and, N_{SD} is equal to the number of subcarriers each of the N_{SYM} OFDM symbols consists of. In some embodiments, the new tone mapping spacing will provide greater frequency diversity. In some embodiments the new tone mappings of tables 510, 520, 530, and 540 will provide greater frequency diversity and may increase the spectral efficiency.

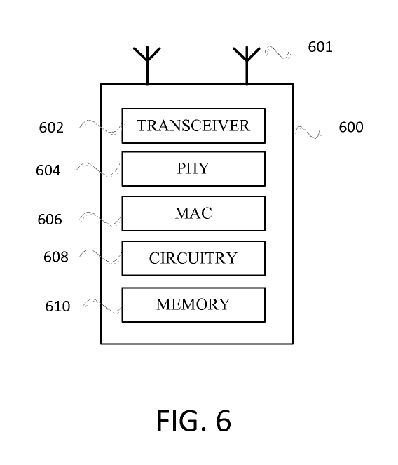

FIG. 6 illustrates a HEW device 600 in accordance with some embodiments. HEW device 600 may be an HEW compliant device that may be arranged to communicate with one or more other HEW devices, such as HEW STAs 104 (FIG. 1) or master station 102 (FIG. 1) as well as communicate with legacy devices 106 (FIG. 1). HEW STAs 104 and legacy devices 106 may also be referred to as HEW devices and legacy STAs, respectively. HEW device 600 may be suitable for operating as master station 102 (FIG. 1) or a HEW STA 104 (FIG. 1). In accordance with embodiments, HEW device 600 may include, among other things, a transmit/receive element 601 (for example an antenna), a transceiver 602, physical (PHY) circuitry 604, and media access control (MAC) circuitry 606. PHY circuitry 604 and MAC circuitry 606 may be HEW compliant layers and may also be compliant with one or more legacy IEEE 802.13 standards. MAC circuitry 606 may be arranged to configure packets such as a physical layer convergence procedure (PLCP) protocol data unit (PPDUs) and arranged to transmit and receive PPDUs, among other things. HEW device 600 may also include circuitry 608 and memory 610 configured to perform the various operations described herein. The circuitry 608 may be coupled to the transceiver 602, which may be coupled to the transmit/receive element 601. While FIG. 6 depicts the circuitry 608 and the transceiver 602 as separate components, the circuitry 608 and the transceiver 602 may be integrated together in an electronic package or chip.

In some embodiments, the MAC circuitry 606 may be arranged to contend for a wireless medium during a contention period to receive control of the medium for the HEW control period and configure an HEW PPDU. In some embodiments, the MAC circuitry 606 may be arranged to contend for the wireless medium based on channel contention settings, a transmitting power level, and a CCA level.

The PHY circuitry 604 may be arranged to transmit the HEW PPDU. The PHY circuitry 604 may include circuitry for modulation/demodulation, upconversion/downconversion, filtering, amplification, etc. In some embodiments, the circuitry 608 may include one or more processors. The circuitry 608 may be configured to perform functions based on instructions being stored in a RAM or ROM, or based on special purpose circuitry. The circuitry 608 may include processing circuitry and/or transceiver circuitry in accordance with some embodiments. The circuitry 608 may include a processor such as a general purpose processor or special purpose processor. The circuitry 608 may implement one or more functions associated with transmit/receive elements 601, the transceiver 602, the PHY circuitry 604, the MAC circuitry 606, and/or the memory 610.

In some embodiments, the circuitry 608 may be configured to perform one or more of the functions and/or methods described herein and/or in conjunction with FIGS. 1-6 such as decoding or encoding LDPCs with a larger code word size than legacy LDPCs code word sizes.

In some embodiments, the transmit/receive elements 601 may be two or more antennas that may be coupled to the PHY circuitry 604 and arranged for sending and receiving signals including transmission of the HEW packets. The transceiver 602 may transmit and receive data such as HEW PPDU and packets that include an indication that the HEW device 600 should adapt the channel contention settings according to settings included in the packet. The memory 610 may store information for configuring the other circuitry to perform operations for configuring and transmitting HEW packets and performing the various operations to perform one or more of the functions and/or methods described herein and/or in conjunction with FIGS. 1-6.

In some embodiments, the HEW device 600 may be configured to communicate using OFDM communication signals over a multicarrier communication channel. In some embodiments, HEW device 600 may be configured to communicate in accordance with one or more specific communication standards, such as the Institute of Electrical and Electronics Engineers (IEEE) standards including IEEE 802.11-2012, 802.11n-2009, 802.11ac-2013, 802.11ax, DensiFi, standards and/or proposed specifications for WLANs, or other standards as described in conjunction with FIG. 1, although the scope of the invention is not limited in this respect as they may also be suitable to transmit and/or receive communications in accordance with other techniques and standards. In some embodiments, the HEW device 600 may use 4× symbol duration of 802.11n or 802.11 ac.

In some embodiments, an HEW device 600 may be part of a portable wireless communication device, such as a personal digital assistant (PDA), a laptop or portable computer with wireless communication capability, a web tablet, a wireless telephone, a smartphone, a wireless headset, a pager, an instant messaging device, a digital camera, an access point, a television, a medical device (e.g., a heart rate monitor, a blood pressure monitor, etc.), an access point, a base station, a transmit/receive device for a wireless standard such as 802.11 or 802.16, or other device that may receive and/or transmit information wirelessly. In some embodiments, the mobile device may include one or more of a keyboard, a display, a non-volatile memory port, multiple antennas, a graphics processor, an application processor, speakers, and other mobile device elements. The display may be an LCD screen including a touch screen.

The transmit/receive element 601 may comprise one or more directional or omnidirectional antennas, including, for example, dipole antennas, monopole antennas, patch antennas, loop antennas, microstrip antennas or other types of antennas suitable for transmission of RF signals. In some multiple-input multiple-output (MIMO) embodiments, the antennas may be effectively separated to take advantage of spatial diversity and the different channel characteristics that may result.

Although the HEW device 600 is illustrated as having several separate functional elements, one or more of the functional elements may be combined and may be implemented by combinations of software-configured elements, such as processing elements including digital signal processors (DSPs), and/or other hardware elements. For example, some elements may comprise one or more microprocessors, DSPs, field-programmable gate arrays (FPGAs), application specific integrated circuits (ASICs), radio-frequency integrated circuits (RFICs) and combinations of various hardware and logic circuitry for performing at least the functions described herein. In some embodiments, the functional elements may refer to one or more processes operating on one or more processing elements.

In example embodiments, instructions contained in or on a non-transitory computer-readable storage medium are configured to perform the methods and functions herein described in conjunction with FIGS. 1-6. Those instructions may then be read and executed by one or more processors to enable performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read only memory (ROM); random access memory (RAM); magnetic disk storage media; optical storage media; a flash memory, etc.

The following examples pertain to further embodiments. Example 1 is an apparatus of a high-efficiency wireless local-area network (HEW) device including transceiver circuitry and processing circuitry configured to encode a packet using a low-density parity check (LDPC) code four times longer than a legacy LDPC code and in accordance with a channel code, and transmit the packet.

In Example 2, the subject matter of Example 1 can optionally include where the LDPC code four times longer than the legacy LDPC code is 7776 bits and the legacy LDPC code is 1944 bits.

In Example 3, the subject matter of Example 1 or Example 2 can optionally include where the transceiver circuitry and processing circuitry is further configured to transmit the packet in accordance with 1024 quadrature amplitude modulation (QAM), and wherein the channel code is one from the following group: 1/2 and 2/3.

In Example 4, the subject matter of any of Examples 1-3 can optionally include where the LDPC code four times longer than the legacy LDPC code is 7776 bits and the legacy LDPC code is one from the following group: 648 bits, 1296 bits, and 1944 bits.

In Example 5, the subject matter of any of Examples 1-4 can optionally include where the transceiver circuitry and processing circuitry is further configured to transmit the packet in accordance with 256 quadrature amplitude modulation (QAM) and in accordance with a LDPC subcarrier mapping of 4 for a 20 MHz sub-channel, 6 for a 40 MHz sub-channel, and 9 for an 80 MHz sub-channel.

In Example 6, the subject matter of any of Examples 1-5 can optionally include where the transceiver circuitry and processing circuitry is further configured to transmit the packet in accordance with a 1024 quadrature amplitude modulation (QAM) and in accordance with a LDPC subcarrier mapping of 32 or 64 subcarriers for a 20 MHz sub-channel, 48 or 96 subcarriers for a 40 MHz sub-channel, and 72 or 144 subcarriers for an 80 MHz sub-channel.

In Example 7, the subject matter of any of Examples 1-6 can optionally include where the transceiver circuitry and processing circuitry is further configured to transmit the packet in accordance with 1024 quadrature amplitude modulation (QAM) and in accordance with a LDPC subcarrier mapping of 16 subcarriers for a 20 MHz sub-channel, 24 subcarriers for a 40 MHz sub-channel, and 36 subcarriers for an 80 MHz sub-channel.

In Example 8, the subject matter of any of Examples 1-7 can optionally include where the transceiver circuitry and processing circuitry is further configured to transmit the packet in accordance with a LDPC subcarrier mapping that is determined by d_(k,l,n)̂′, where d_(k,l,n)̂′=d_(t(k),l,n), and where t(k)=D_TM*(k mod N_SD/D_TM)+└(k*D_TM)/N_SD┘; k=0, 1, . . . , NSD−1; 1=1, . . . , NSS; n=0, 1, . . . , NSYM−1; NSS is the number of spatial streams; NSYM is the number of OFDM symbols; and, NSD is equal to the number of subcarriers of each of the NSYM OFDM symbols.

In Example 9, the subject matter of any of Examples 1-8 can optionally include where the HEW device is at least one from the following group a HEW station, a master station, an Institute of Electrical and Electronic Engineers (IEEE) 802.11 ax access point, and an IEEE 802.11 ax station.

In Example 10, the subject matter of any of Examples 1-9 can optionally include where the transceiver circuitry and processing circuitry is further configured to transmit the packet in accordance with orthogonal frequency division multiple access (OFDMA) and in accordance with Institute of Electrical and Electronic Engineers (IEEE) 802.11 ax.

In Example 11, the subject matter of any of Examples 1-10 can optionally include where the transceiver circuitry and processing circuitry is further configured to transmit the packet in accordance with 1024 quadrature amplitude modulation (QAM) and in accordance with a LDPC subcarrier mapping with an increased distance between sub-carriers compared with a legacy Institute of Electrical and Electronic Engineers 802.11 standard.

In Example 12, the subject matter of any of Examples 1-11 can optionally include memory coupled to the transceiver circuitry and processing circuitry; and one or more antennas coupled to the transceiver circuitry.

In Example 13 is a non-transitory computer-readable storage medium that stores instructions for execution by one or more processors, where the instructions are to configure the one or more processors to cause a high-efficiency wireless local-area network (HEW) master station to encode a packet using a low-density parity check (LDPC) code four times longer than a legacy LDPC code and in accordance with a channel code, and transmit the packet.

In Example 14, the subject matter of Example 13 can optionally include where the LDPC code four times longer than the legacy LDPC code is 7776 bits and the legacy LDPC code is 1944 bits.

In Example 15, the subject matter of Example 14 can optionally include where the instructions further configure the one or more processors to cause the HEW master station to transmit the packet in accordance with 1024 QAM, and wherein the channel code is one from the following group: 1/2 and 2/3.

In Example 16, the subject matter of any of Examples 13-15 can optionally include where the instructions further configure the one or more processors to cause the HEW master station to transmit the packet in accordance with 1024 QAM and in accordance with a LDPC subcarrier mapping with an increased distance between sub-carriers compared with a legacy Institute of Electrical and Electronic Engineers 802.11 standard.

Example 17 is an apparatus of a high-efficiency wireless local-area network (HEW) device including transceiver circuitry and processing circuitry configured to receive a packet in accordance with 1024 quadrature amplitude modulation (QAM), and decode the packet in accordance with a low-density parity check (LDPC) code four times longer than a legacy LDPC code.

In Example 18, the subject matter of Example 17 can optionally include where the LDPC code four times longer than the legacy LDPC code is 7776 bits and the legacy LDPC code is 1944 bits.

In Example 19, the subject matter of Example 17 or Example 18 can optionally include where the transceiver circuitry and processing circuitry is further configured to decode the packet in accordance with a channel code that is one from the following group: 1/2 and 2/3.

In Example 20, the subject matter of any of Examples 17-19 can optionally include where the LDPC code four times longer than the legacy LDPC code is 7776 bits and the legacy LDPC code is one from the following group: 648 bits, 1296 bits, and 1944 bits.

In Example 21, the subject matter of any of Examples 17-20 can optionally include where the transceiver circuitry and processing circuitry is further configured to decode the packet in accordance with a LDPC subcarrier mapping with an increased distance between sub-carriers compared with a legacy Institute of Electrical and Electronic Engineers 802.11 standard.

In Example 22, the subject matter of any of Examples 17-21 can optionally include memory coupled to the transceiver circuitry and processing circuitry; and one or more antennas coupled to the transceiver circuitry.

Example 23 is a method performed by a high-efficiency wireless local-area network (HEW) device. The method including encoding a packet using a low-density parity check (LDPC) code four times longer than a legacy LDPC code and in accordance with a channel code, and transmit the packet.

In Example 24, the subject matter of Example 23 can optionally include where the LDPC code four times longer than the legacy LDPC code is 7776 bits and the legacy LDPC code is 1944 bits.

In Example 25, the subject matter of Example 23 or Example 24 can optionally include transmitting the packet in accordance with 1024 quadrature amplitude modulation (QAM), and wherein the channel code is one from the following group: 1/2 and 2/3.

Example 26 is an apparatus of a high-efficiency wireless local-area network (HEW) device. The apparatus including means for encoding a packet using a low-density parity check (LDPC) code four times longer than a legacy LDPC code and in accordance with a channel code, and means for transmitting the packet.

In Example 27, the subject matter of Example 26 can optionally include where the LDPC code four times longer than the legacy LDPC code is 7776 bits and the legacy LDPC code is 1944 bits.

In Example 28, the subject matter of Example 26 or Example 27 can optionally include means for transmitting the packet in accordance with 1024 quadrature amplitude modulation (QAM), and wherein the channel code is one from the following group: 1/2 and 2/3.

In Example 29, the subject matter of any of Examples 26-28 can optionally include where the LDPC code four times longer than the legacy LDPC code is 7776 bits and the legacy LDPC code is one from the following group: 648 bits, 1296 bits, and 1944 bits.

In Example 30, the subject matter of any of Examples 26-29 can optionally include means for transmitting the packet in accordance with 256 quadrature amplitude modulation (QAM) and in accordance with a LDPC subcarrier mapping of 4 for a 20 MHz sub-channel, 6 for a 40 MHz sub-channel, and 9 for an 80 MHz sub-channel.

In Example 31, the subject matter of any of Examples 26-30 can optionally include means for transmitting the packet in accordance with a 1024 quadrature amplitude modulation (QAM) and in accordance with a LDPC subcarrier mapping of 32 or 64 subcarriers for a 20 MHz sub-channel, 48 or 96 subcarriers for a 40 MHz sub-channel, and 72 or 144 subcarriers for an 80 MHz sub-channel.

In Example 32, the subject matter of any of Examples 26-31 can optionally include means for transmitting the packet in accordance with 1024 quadrature amplitude modulation (QAM) and in accordance with a LDPC subcarrier mapping of 16 subcarriers for a 20 MHz sub-channel, 24 subcarriers for a 40 MHz sub-channel, and 36 subcarriers for an 80 MHz sub-channel.

In Example 33, the subject matter of any of Examples 26-32 can optionally include means for transmitting the packet in accordance with a LDPC subcarrier mapping that is determined by d_(k,l,n)̂′, where d_(k,l,n)̂′=d_(t(k),l,n), and where t(k)=D_TM*(k mod N_SD/D_TM)+└(k*D_TM)/N_SD┘; k=0, 1, . . . , NSD−1; 1=1, . . . , NSS; n=0, 1, . . . , NSYM−1; NSS is the number of spatial streams; NSYM is the number of OFDM symbols; and, NSD is equal to the number of subcarriers of each of the NSYM OFDM symbols.

In Example 34, the subject matter of any of Examples 26-33 can optionally include where the HEW device is at least one from the following group: a HEW station, a master station, an Institute of Electrical and Electronic Engineers (IEEE) 802.11 ax access point, and an IEEE 802.11 ax station.

In Example 35, the subject matter of any of Examples 26-34 can optionally include means for transmitting the packet in accordance with orthogonal frequency division multiple access (OFDMA) and in accordance with Institute of Electrical and Electronic Engineers (IEEE) 802.11 ax.

In Example 36, the subject matter of any of Examples 26-35 can optionally include means for transmitting the packet in accordance with 1024 quadrature amplitude modulation (QAM) and in accordance with a LDPC subcarrier mapping with an increased distance between sub-carriers compared with a legacy Institute of Electrical and Electronic Engineers 802.11 standard.

In Example 37, the subject matter of any of Examples 26-36 can optionally include memory coupled to the transceiver circuitry and processing circuitry; and one or more antennas coupled to the transceiver circuitry.

Example 38 is an apparatus of a high-efficiency wireless local-area network (HEW) device. The apparatus including means for receiving a packet in accordance with 1024 quadrature amplitude modulation (QAM), and means for decoding the packet in accordance with a low-density parity check (LDPC) code four times longer than a legacy LDPC code.

In Example 39, the subject matter of Example 38 can optionally include where the LDPC code four times longer than the legacy LDPC code is 7776 bits and the legacy LDPC code is 1944 bits.

In Example 40, the subject matter of Example 38 or Example 39 can optionally include means for decoding the packet in accordance with a channel code that is one from the following group: 1/2 and 2/3.

In Example 41, the subject matter of any of Examples 38-40 can optionally include where the LDPC code four times longer than the legacy LDPC code is 7776 bits and the legacy LDPC code is one from the following group: 648 bits, 1296 bits, and 1944 bits.

In Example 42, the subject matter of any of Examples 38-41 can optionally include means for decoding the packet in accordance with a LDPC subcarrier mapping with an increased distance between sub-carriers compared with a legacy Institute of Electrical and Electronic Engineers 802.11 standard.

In Example 43, the subject matter of any of Examples 38-42 can optionally include memory coupled to the transceiver circuitry and processing circuitry; and one or more antennas coupled to the transceiver circuitry.

The Abstract is provided to comply with 37 C.F.R. Section 1.72(b) requiring an abstract that will allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

What is claimed is:

1. An apparatus of a high-efficiency wireless local-area network (HEW) device comprising transceiver circuitry and processing circuitry configured to:
encode a packet using a low-density parity check (LDPC) code four times longer than a legacy LDPC code and in accordance with a channel code; and
transmit the packet.

2. The apparatus of claim 1, wherein the LDPC code four times longer than the legacy LDPC code is 7776 bits and the legacy LDPC code is 1944 bits.

3. The apparatus of claim 1, wherein the transceiver circuitry and processing circuitry is further configured to:
transmit the packet in accordance with 1024 quadrature amplitude modulation (QAM), and wherein the channel code is one from the following group: 1/2 and 2/3.

4. The apparatus of claim 1, wherein the LDPC code four times longer than the legacy LDPC code is 7776 bits and the legacy LDPC code is one from the following group: 648 bits, 1296 bits, and 1944 bits.

5. The apparatus of claim 1, wherein the transceiver circuitry and processing circuitry is further configured to:
transmit the packet in accordance with 256 quadrature amplitude modulation (QAM) and in accordance with a LDPC subcarrier mapping of 4 for a 20 MHz sub-channel, 6 for a 40 MHz sub-channel, and 9 for an 80 MHz sub-channel.

6. The apparatus of claim 1, wherein the transceiver circuitry and processing circuitry is further configured to:
transmit the packet in accordance with a 1024 quadrature amplitude modulation (QAM) and in accordance with a LDPC subcarrier mapping of 32 or 64 subcarriers for a 20 MHz sub-channel, 48 or 96 subcarriers for a 40 MHz sub-channel, and 72 or 144 subcarriers for an 80 MHz sub-channel.

7. The apparatus of claim 1, wherein the transceiver circuitry and processing circuitry is further configured to:
transmit the packet in accordance with 1024 quadrature amplitude modulation (QAM) and in accordance with a LDPC subcarrier mapping of 16 subcarriers for a 20 MHz sub-channel, 24 subcarriers for a 40 MHz sub-channel, and 36 subcarriers for an 80 MHz sub-channel.

8. The apparatus of claim 1, wherein the transceiver circuitry and processing circuitry is further configured to:
transmit the packet in accordance with a LDPC subcarrier mapping that is determined by \acute{d}_{k,l,n}, where \acute{d}_{k,l,n}=d_{t(k),l,n}, and where
$$t ( k ) = {D}_{TM} * ( k mod \frac{ {N}_{SD}}{{D}_{TM}} ) + ⌊ \frac{k * {D}_{TM}}{{N}_{SD}} ⌋ ;$$
k=0, 1, . . . , N_{SD}−1; l=1, . . . , N_{SS}; n=0, 1, . . . , N_{SYM}−1; N_{SS} is the number of spatial streams; N_{SYM} is the number of OFDM symbols; and, N_{SD} is equal to the number of subcarriers of each of the N_{SYM} OFDM symbols.

9. The apparatus of claim 1, wherein the HEW device is at least one from the following group: a HEW station, a master station, an Institute of Electrical and Electronic Engineers (IEEE) 802.11 ax access point, and an IEEE 802.11 ax station.

10. The apparatus of claim 1, wherein the transceiver circuitry and processing circuitry is further configured to:
transmit the packet in accordance with orthogonal frequency division multiple access (OFDMA) and in accordance with Institute of Electrical and Electronic Engineers (IEEE) 802.11 ax.

11. The apparatus of claim 1, wherein the transceiver circuitry and processing circuitry is further configured to:
transmit the packet in accordance with 1024 quadrature amplitude modulation (QAM) and in accordance with a LDPC subcarrier mapping with an increased distance between sub-carriers compared with a legacy Institute of Electrical and Electronic Engineers 802.11 standard.

12. The apparatus of claim 1, further comprising memory coupled to the transceiver circuitry and processing circuitry; and one or more antennas coupled to the transceiver circuitry.

13. A non-transitory computer-readable storage medium that stores instructions for execution by one or more processors, the instructions to configure the one or more processors to cause a high-efficiency wireless local-area network (HEW) master station to:
encode a packet using a low-density parity check (LDPC) code four times longer than a legacy LDPC code and in accordance with a channel code; and
transmit the packet.

14. The non-transitory computer-readable storage medium of claim 13, wherein the LDPC code four times longer than the legacy LDPC code is 7776 bits and the legacy LDPC code is 1944 bits.

15. The non-transitory computer-readable storage medium of claim 13, wherein the instructions further configure the one or more processors to cause the HEW master station to:
transmit the packet in accordance with 1024 QAM, and wherein the channel code is one from the following group: 1/2 and 2/3.

16. The non-transitory computer-readable storage medium of claim 13, wherein the instructions further configure the one or more processors to cause the HEW master station to:
transmit the packet in accordance with 1024 QAM and in accordance with a LDPC subcarrier mapping with an increased distance between sub-carriers compared with a legacy Institute of Electrical and Electronic Engineers 802.11 standard.

17. An apparatus of a high-efficiency wireless local-area network (HEW) device comprising transceiver circuitry and processing circuitry configured to:
receive a packet in accordance with 1024 quadrature amplitude modulation (QAM); and
decode the packet in accordance with a low-density parity check (LDPC) code four times longer than a legacy LDPC code.

18. The apparatus of claim 17, wherein the LDPC code four times longer than the legacy LDPC code is 7776 bits and the legacy LDPC code is 1944 bits.

19. The apparatus of claim 17, wherein the transceiver circuitry and processing circuitry is further configured to:
decode the packet in accordance with a channel code that is one from the following group: 1/2 and 2/3.

20. The apparatus of claim 17, wherein the LDPC code four times longer than the legacy LDPC code is 7776 bits and the legacy LDPC code is one from the following group: 648 bits, 1296 bits, and 1944 bits.

21. The apparatus of claim 17, wherein the transceiver circuitry and processing circuitry is further configured to:
decode the packet in accordance with a LDPC subcarrier mapping with an increased distance between sub-carriers compared with a legacy Institute of Electrical and Electronic Engineers 802.11 standard.

22. The apparatus of claim 17, further comprising memory coupled to the transceiver circuitry and processing circuitry; and one or more antennas coupled to the transceiver circuitry.

23. A method performed by a high-efficiency wireless local-area network (HEW) device, the method comprising:
encoding a packet using a low-density parity check (LDPC) code four times longer than a legacy LDPC code and in accordance with a channel code; and
transmit the packet.

24. The method of claim 23, wherein the LDPC code four times longer than the legacy LDPC code is 7776 bits and the legacy LDPC code is 1944 bits.

25. The method of claim 23, further comprising:
transmitting the packet in accordance with 1024 quadrature amplitude modulation (QAM), and wherein the channel code is one from the following group: 1/2 and 2/3.
